(19) United States
(12) Patent Application Publication
(10) Pub. No.: US 2007/0026149 A1
(43) Pub. Date: Feb. 1, 2007

(54) Semiconductor manufacturing apparatus and method of manufacturing semiconductor device

(76) Inventors: Takashi Shimizu, Yokohama-Shi (JP); Kazuo Saki, Kawasaki-Shi (JP); Kazuhiro Nishiki, Fujisawa-Shi (JP); Akihito Yamamoto, Kanagawa-Ken (JP); Shinji Mori, Yokohama-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/494,735

(22) Filed: Jul. 28, 2006

(30) Foreign Application Priority Data
Jul. 29, 2005 (JP) 2005-221657

(51) Int. Cl. C23C 16/00

(52) U.S. Cl. 427/248.1

(57) ABSTRACT

In a process of annealing an insulating film such as a silicon oxide film (SiO₂) or a silicon oxynitride film (SiON) provided in a processing chamber 6 within an atmosphere of an inert gas 2 guided from a first mass flow controller 3 via a gas inlet 7, an amount of SiO sublimated from the surface of the insulating film in the processing chamber 6 is measured by a mass spectrometer 10, and an amount of oxygen gas 4 guided to the processing chamber 6 from a second mass flow controller 5 is controlled by a controller 1 so that the SiO concentration does not exceed a predetermined level, thereby effectively controlling the SiO sublimation. As a result, the film deterioration caused by the SiO sublimation is prevented and an insulating film having a high reliability and good characteristics can be formed in a controllable manner.

### CROSS-REFERENCE TO RELATED APPLICATION

This application is based upon and claims the benefit of priority from prior Japanese Patent Application No. 2005-221657, filed on Jul. 29, 2005, the entire contents of which are incorporated herein by reference.

### BACKGROUND OF THE INVENTION

1. Field of the Invention

The present invention relates to a semiconductor manufacturing apparatus and a method of manufacturing a semiconductor device. In particular, the present invention relates to an apparatus and a method of manufacturing a semiconductor device in which sublimation of silicon oxide from an insulating film can be curbed during a process of performing nitrogen annealing or oxygen annealing on the insulating film containing silicon oxide.

2. Background Art

Generally, an SiO₂ film (silicon oxide film) or SiON film (silicon oxynitride film) is used as a gate insulating film of a transistor. The thickness of such a gate insulating film has been decreased to the level of a few nm to 1 nm or less as the integration and miniaturization of LSIs have advanced. Japanese Patent Laid-Open Publication No. 2003-77842, for example, discloses a technique for manufacturing such a semiconductor device.

However, when nitrogen annealing or oxygen annealing is performed on such an ultra thin film of silicon oxide formed on a Si substrate (silicon substrate), it is necessary to reliably curb the sublimation of SiO (silicon monoxide) from the thin film.

The sublimation of SiO occurs when the partial pressure of O₂ or H₂O in an atmosphere reaches a predetermined value or less during a heat treatment.

Specifically, when the process of annealing the gate insulating film is performed in an inert gas atmosphere at a high temperature or in an oxygen atmosphere under a low oxygen partial pressure at a high temperature, the sublimation of SiO advances, and so-called “film deterioration” occurs. The film deterioration may cause leakage current in a manufactured transistor, thereby interfering with the normal transistor operation.

On the other hand, when O₂, for example, is added to the atmosphere, and the O₂ partial pressure is increased, the sublimation of SiO is curbed, thereby solving the problem of the film deterioration.

However, if the O₂ partial pressure is too high, although the sublimation of SiO can be sufficiently curbed, the oxidation of the Si substrate advances, thereby increasing the thicknesses of the SiO₂ film or the SiON film. Thus, if the annealing processing, etc. is performed after the formation of an ultra thin film, and if the O₂ partial pressure is set to be too high in order to curb the sublimation of SiO, a problem arises in that it becomes difficult to decrease the thicknesses of films.

As described above, when a heat treatment is performed on an SiO₂ film or SiON film, a trade-off should be considered between the problem of SiO sublimation and the problem of film deterioration.

That is to say, it has been said to be ideal that when a heat treatment such as the annealing processing is performed on an ultra thin film such as an insulating film containing silicon oxide, the O₂ partial pressure should be controlled to be at a lowest level at which the sublimation of SiO does not occur.

However, actually, the lowest O₂ partial pressure level changes in accordance with the thickness of the SiO₂ film or SiON film. Furthermore, in the case of the SiON film, the lowest O₂ partial pressure level also changes in accordance with the nitrogen concentration in the film.

Moreover, the lowest O₂ partial pressure level also changes due to the fluctuations of heat treatment temperature, and the fluctuations of the concentration in residual oxygen originally existing in the processing chamber.

In order to always prevent the occurrence of SiO sublimation caused by such fluctuations, a high O₂ partial pressure should be set, allowing a sufficient margin. Depending on the situation, in some cases, the problem of film thickness should be sacrificed.

As described above, in a conventional semiconductor manufacturing apparatus, at the time of performing a heat treatment such as the process of annealing an insulating film containing silicon oxide, the SiO sublimation cannot be optimally curbed. Accordingly, a problem arises in that it is difficult to form an ultra thin film with a high reliability.

### SUMMARY OF THE INVENTION

A semiconductor manufacturing apparatus according to a first embodiment of the present invention includes:

a processing chamber for performing a heat treatment on a semiconductor wafer, to which an oxidant gas can be supplied;

a monitor monitoring a concentration of silicon monoxide contained in exhaust gas from the processing chamber; and

a controller controlling an amount of the oxidant gas supplied to the processing chamber based on the concentration of silicon monoxide monitored by the monitor.

A semiconductor manufacturing apparatus according to a second embodiment of the present invention includes:

a processing chamber for performing a heat treatment on a semiconductor wafer, to which an oxidant gas can be supplied;

a monitor monitoring a concentration of silicon monoxide within the processing chamber; and

a controller controlling an amount of the oxidant gas supplied to the processing chamber based on the concentration of silicon monoxide monitored by the monitor.

A method of manufacturing a semiconductor device according to a third embodiment of the present invention includes:

supplying an oxidant gas to a processing chamber for performing a heat treatment on a semiconductor wafer;

monitoring, with a monitor, a concentration of silicon monoxide contained in exhaust gas from the processing chamber; and

controlling, with a controller, an amount of the oxidant gas supplied to the processing chamber based on the concentration of silicon monoxide monitored using the monitor.

A method of manufacturing a semiconductor device according to a fourth embodiment of the present invention includes:

supplying an oxidant gas to a processing chamber for performing a heat treatment on a semiconductor wafer;

monitoring, with a monitor, a concentration of silicon monoxide contained in an atmosphere within the processing chamber; and

controlling, with a controller, an amount of the oxidant gas supplied to the processing chamber based on the concentration of silicon monoxide monitored using the monitor.

According to the embodiments of the present invention, it is possible to manufacture a semiconductor device including an insulating film having a high reliability and a high performance property.

### BRIEF DESCRIPTION OF THE DRAWINGS

FIG. 1 is a schematic block diagram of a semiconductor manufacturing apparatus according to a first embodiment of the present invention.

FIG. 2 is a measurement diagram for explaining the operation of the structure shown in FIG. 1.

FIG. 3 is a schematic block diagram of a semiconductor manufacturing apparatus according to a second embodiment of the present invention.

FIG. 4 is a schematic block diagram of a semiconductor manufacturing apparatus according to a third embodiment of the present invention.

FIG. 5 is a schematic block diagram of a semiconductor manufacturing apparatus according to a fourth embodiment of the present invention.

### DESCRIPTION OF THE EMBODIMENTS

Hereinafter, the best mode for carrying out the present invention will be described with reference to the accompanying drawings.

### First Embodiment

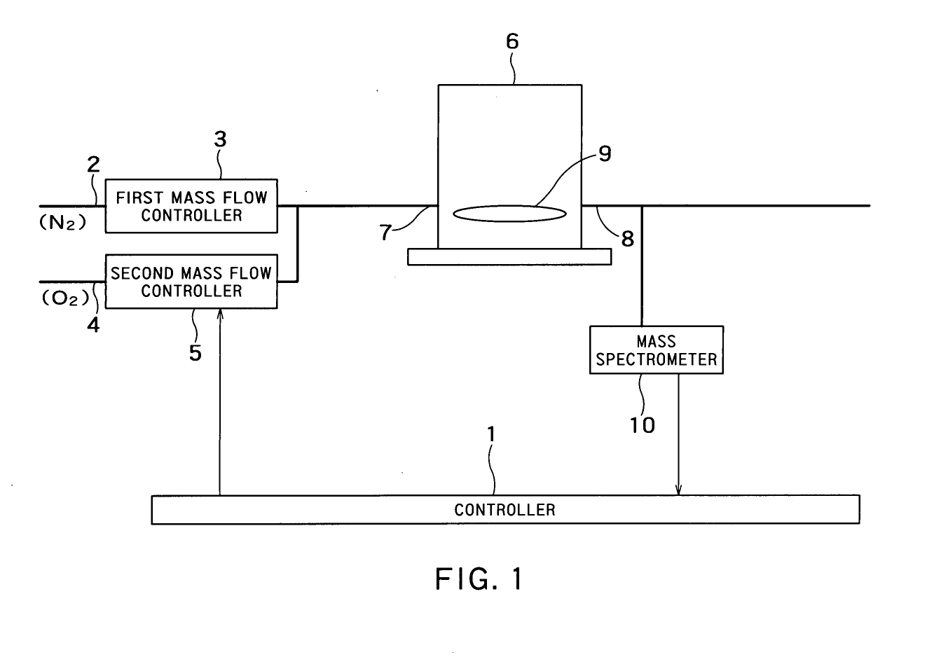

FIG. 1 is a schematic block diagram of a semiconductor manufacturing apparatus according to a first embodiment of the present invention. As shown in FIG. 1, a wafer to be processed 9 including a silicon substrate is provided into a processing chamber 6. An inert gas 2 such as N₂, Ar, and He, and oxygen (O₂) gas 4, for example, serving as an oxidant gas working on silicon, are guided into the processing chamber 6 through a gas inlet 7. The flow of the inert gas 2 is controlled by a first mass flow controller 3, and the flow of the oxygen gas 4 is controlled by a second mass flow controller 5. Besides O₂, other examples of the oxidant gas are H₂O and N₂O. In the case of using H₂O, however, the flow rate control is not performed by directly controlling the flow rate of H₂O, but, generally, by separately controlling the flow rates of H₂ gas and O₂ gas by mass flow controllers, adding these gasses, and burning the mixed gas to generate H₂O. The gasses in the processing chamber 6 are discharged from a gas outlet 8. The components of the gasses at the gas outlet 8 are measured by a mass spectrometer 10 and the measurement result is sent to a controller 1. Based on the measurement result sent from the mass spectrometer 10, the controller 1 controls the second mass flow controller 5 to control the flow rate of the oxygen gas 4 introduced into the processing chamber 6 through the gas inlet 7.

The operation of the aforementioned structure will be described in detail below.

The wafer to be processed 9 includes a silicon substrate, on the surface of which an insulating film of silicon oxide, e.g., an SiO₂ film or SiON film, is formed. The inside of the processing chamber 6 is set to be a high temperature atmosphere of the inert gas 2 introduced from the first mass flow controller 3 via the gas inlet 7 and the oxygen gas 4 introduced from the second mass flow controller 5 via the gas inlet 7. The annealing processing is performed on the SiO₂ film or SiON film here.

During the annealing processing, when the concentration of the oxygen gas 4 controlled by the second mass flow controller 5 reaches a predetermined value or less, SiO sublimates from the insulating film, on which the annealing processing is performed, and discharged from the gas outlet 8.

The amount of SiO is measured by the mass spectrometer 10 provided to the gas outlet 8, and the measurement result is sent to the controller 1. When the concentration of SiO exceeds a predetermined value, the controller 1 gives instructions to the second mass flow controller 5 to increase the flow rate of the oxygen gas 4.

As a result, the concentration of the oxygen gas 4 in the processing chamber 6 increases, thereby curbing the SiO sublimation from the insulating film. Accordingly, the SiO concentration at the gas outlet 8 measured by the mass spectrometer 10 decreases.

When the SiO concentration measured by the mass spectrometer 10 reaches a predetermined value or less, the controller 1 gives instructions to the second mass flow controller 5 to decrease the flow rate of the oxygen gas 4.

Through the aforementioned control operations, the concentration of the oxygen gas 4 within the processing chamber 6 is controlled so that the SiO concentration measured at the gas outlet 8 is always at a predetermined value or less.

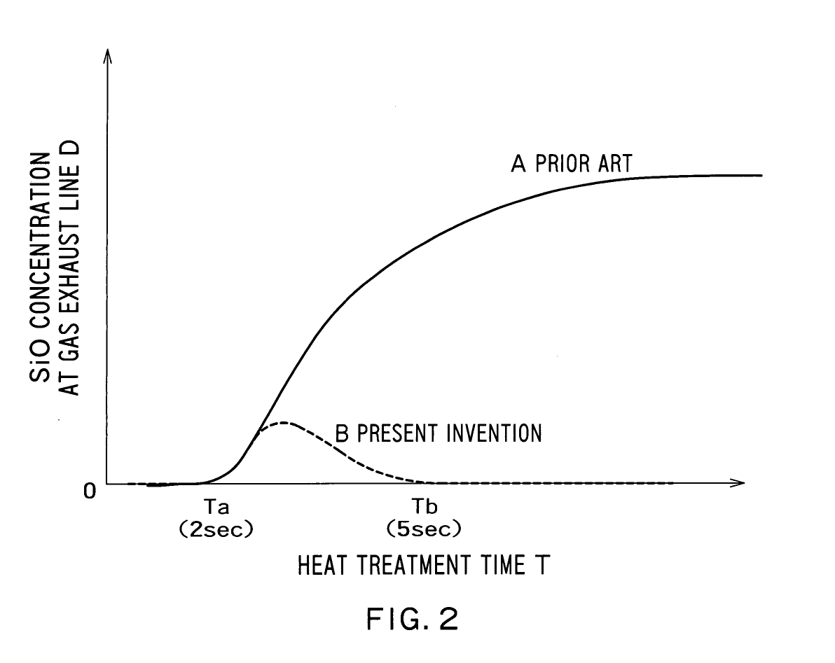

FIG. 2 is a measurement diagram showing the result of the measurement of SiO concentration at the gas outlet 8 measured by the mass spectrometer 10 in a case where a heat treatment is performed on the wafer to be processed 9 with the inside of the processing chamber 6 being set to be N₂ atmosphere at a temperature of 1,050° C. In FIG. 2, the horizontal axis represents time T, and the vertical axis represent SiO concentration D at the gas outlet 8. The curved line A shows the case where the flow rate of the oxygen gas 4 is not controlled by the controller 1, and the curved line B shows the case where the flow rate of the oxygen gas 4 is controlled by the controller 1 by giving instructions to the second mass flow controller 5 so that the SiO concentration measured by the mass spectrometer 10 is set to be at a predetermined value or less.

Immediately after the heat treatment is started, the SiO concentration is zero. As the time passes, SiO sublimates from the insulating film at the surface of the wafer to be processed 9 within the processing chamber 6. As the result, the SiO concentration at the gas outlet 8 increases as the time passes. After the time Ta has passed, the film deterioration of the insulating film reaches a level that cannot be ignored.

If no action is taken, the SiO concentration continuously increases as shown by the curved line A. As a result, the film deterioration of the insulating film on the wafer to be processed 9 continuously advances.

In contrast with this, according to the structure of the first embodiment, the SiO concentration at the gas outlet 8 is measured by the mass spectrometer 10, and when the time Ta has passed and the concentration exceeds a predetermined level, the controller 1 gives instructions to the second mass flow controller 5 to start the supply of the oxygen gas 4 and to control the flow rate thereof. As a result, the partial pressure of the oxygen gas 4 in the processing chamber 6 is increased, thereby curbing the SiO sublimation. As a result, the SiO concentration at the gas outlet 8 gradually decreases and reaches below the predetermined level at the time Tb, as shown by the curved line B.

As a result, it is possible to prevent the film deterioration of the insulating film on the wafer to be processed 9.

At the time Tb when the SiO concentration reaches the predetermined level or less, the flow rate of the oxygen gas 4 is decreased again by the second mass flow controller 5. At this time, the supply of the oxygen gas 4 is not completely stopped, but controlled so that the SiO concentration at the gas outlet 8 is within a predetermined range.

As a result, it is possible to prevent the inconvenience that the flow rate of the oxygen gas 4 is extremely increased, thereby increasing the thickness of the insulating film.

Although the film deterioration of the insulating film has already started when SiO is detected at the gas outlet 8, if the SiO concentration detection sensitivity of the mass spectrometer 10 is sufficiently high, and if the feedback response speed of the controller 1 with respect to the oxygen gas 4 is high, it is possible to curb the film deterioration of the insulating film to be a minimum level, thereby preventing this problem from becoming a crucial one.

### Second Embodiment

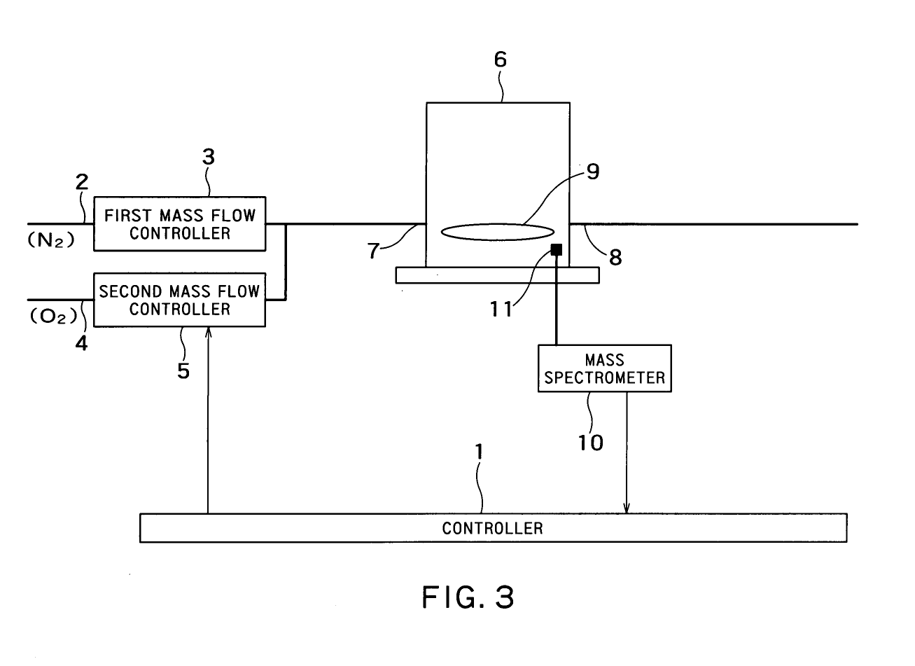

FIG. 3 is a schematic block diagram of a semiconductor manufacturing apparatus according to a second embodiment of the present invention. As shown in FIG. 3, a mass spectrometer 10 is configured to measure the SiO concentration within a processing chamber 6 with a probe 11.

The difference between the first embodiment and the second embodiment lies in that although the concentration of SiO sublimating from the insulating film at the surface of the wafer to be processed 9 is measured at the gas outlet 8 in the first embodiment, the SiO concentration within the processing chamber 6 is directly measured in the second embodiment.

Since the SiO concentration is directly measured within the processing chamber 6 in the second embodiment, it is possible to increase the SiO concentration detection speed, thereby increasing the feedback speed for controlling the flow rate of oxygen gas 4. As a result, it is possible to increase the response speed for curbing the increase in the SiO concentration, thereby curbing the film deterioration of the insulating film more effectively.

### Third Embodiment

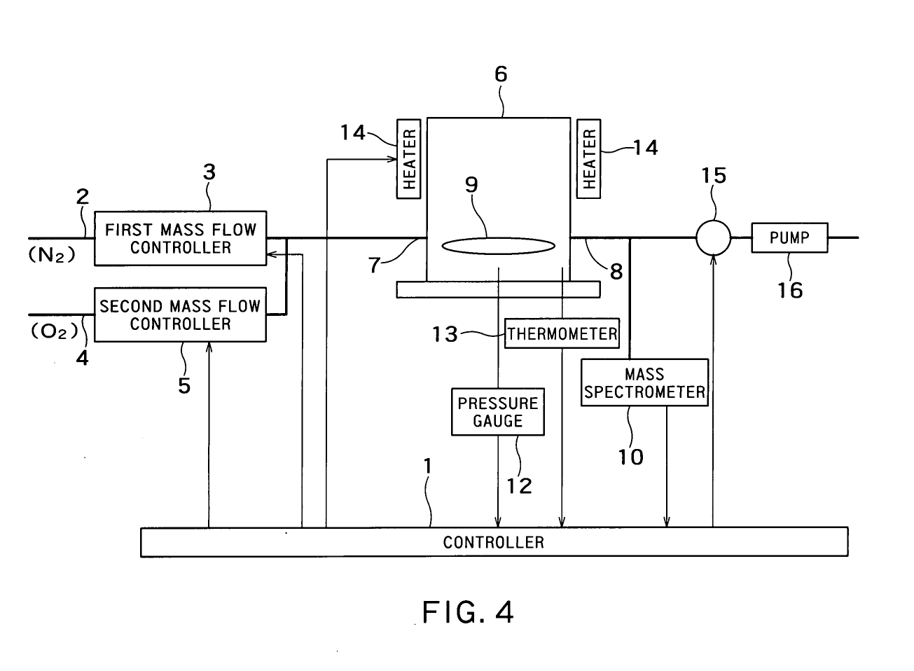

FIG. 4 is a schematic block diagram of a semiconductor manufacturing apparatus according to a third embodiment of the present invention. As shown in FIG. 4, a heater 14 is also provided outside a processing chamber 6, a temperature of which can be controlled based on instructions from a controller 1. A pump 16 is provided at the side of a gas outlet 8 of the processing chamber 6, and before the pump 16 a pressure control valve 15 is provided, thereby adjustably changing the pressure within the processing chamber 6 in accordance with the instructions from the controller 1. In addition, the controller 1 is configured to be able to separately control the amounts of the inert gas 2 and the oxygen gas 4 guided through the gas inlet 7 into the processing chamber 6 by giving instructions to the first mass flow controller 3 and the second mass flow controller 5.

As shown in FIG. 4, the controller 1 controls the flow rate of the oxygen gas 4 using the second mass flow controller 5 in order to control the SiO concentration measured by the mass spectrometer 10 to be within a predetermined range. In addition, the controller 1 controls the pressure control valve 15 connected to the pump 16 in order to maintain the pressure within the processing chamber 6 detected by a pressure indicator 12 to be a predetermined level, and controls the heater 14 in order to maintain a temperature within the processing chamber 6 detected by a thermometer 13 to be a predetermined level.

Moreover, the controller 1 also controls the flow rate of the inert gas 2 through the control of the first mass flow controller 3. Thus, since the controller 1 is able to freely adjust the atmosphere within the processing chamber 6 in accordance with the SiO concentration, it is possible to control the process more freely and more sensitively.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

### Fourth Embodiment

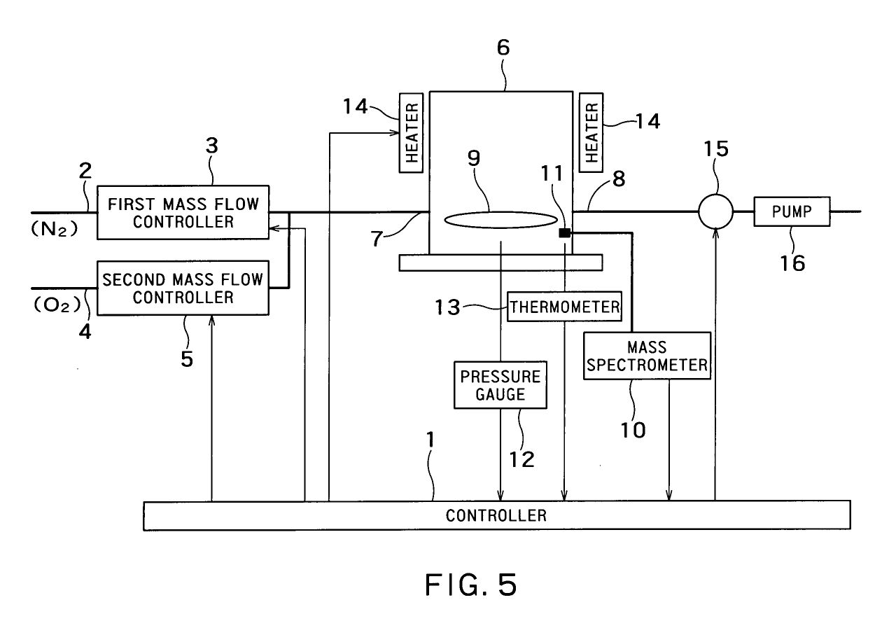

FIG. 5 is a schematic block diagram of a semiconductor manufacturing apparatus according to a fourth embodiment of the present invention. As shown in FIG. 5, a mass spectrometer 10 is configured to measure the SiO concentration within a processing chamber 6 with a probe 11.

1. A semiconductor manufacturing apparatus comprising:
a processing chamber performing a heat treatment on a semiconductor wafer, to which an oxidant gas can be supplied;
a monitor monitoring a concentration of silicon monoxide contained in exhaust gas from the processing chamber; and
a controller controlling an amount of the oxidant gas supplied to the processing chamber based on the concentration of silicon monoxide monitored by the monitor.

2. The semiconductor manufacturing apparatus according to claim 1, wherein the oxidant gas is supplied to the processing chamber via a supply line.

3. The semiconductor manufacturing apparatus according to claim 1, wherein the controller is configured to have a function to control a flow rate of the oxidant gas supplied to the processing chamber so that the concentration of silicon monoxide is controlled to be within a predetermined range based on the concentration of silicon monoxide monitored by the monitor and an amount of a change thereof as time passes.

4. The semiconductor manufacturing apparatus according to claim 1, wherein a supply amount of an inert gas guided to the processing chamber is controllable.

5. The semiconductor manufacturing apparatus according to claim 4, wherein the controller is configured to have a function to control a flow rate of the oxidant gas supplied to the processing chamber so that the concentration of silicon monoxide is controlled to be within a predetermined range based on the concentration of silicon monoxide monitored by the monitor and an amount of a change thereof as time passes, and controls at least one of the supply amount of the inert gas, a pressure within the processing chamber, and a processing temperature within the processing chamber.

6. A semiconductor manufacturing apparatus comprising:
a processing chamber performing a heat treatment on a semiconductor wafer, to which an oxidant gas can be supplied;
a monitor monitoring a concentration of silicon monoxide within the processing chamber; and
a controller controlling an amount of the oxidant gas supplied to the processing chamber based on the concentration of silicon monoxide monitored by the monitor.

7. The semiconductor manufacturing apparatus according to claim 6, wherein the oxidant gas is supplied to the processing chamber via a supply line.

8. The semiconductor manufacturing apparatus according to claim 6, wherein the controller is configured to have a function to control a flow rate of the oxidant gas supplied to the processing chamber so that the concentration of silicon monoxide is controlled to be within a predetermined range based on the concentration of silicon monoxide monitored by the monitor and an amount of a change thereof as time passes.

9. The semiconductor manufacturing apparatus according to claim 6, wherein a supply amount of an inert gas guided to the processing chamber is controllable.

10. The semiconductor manufacturing apparatus according to claim 9, wherein the controller is configured to have a function to control a flow rate of the oxidant gas supplied to the processing chamber so that the concentration of silicon monoxide is controlled to be within a predetermined range based on the concentration of silicon monoxide monitored by the monitor and an amount of a change thereof as time passes, and controls at least one of the supply amount of the inert gas, a pressure within the processing chamber, and a processing temperature within the processing chamber.

11. A method of manufacturing a semiconductor device comprising:
supplying an oxidant gas to a processing chamber for performing a heat treatment on a semiconductor wafer;
monitoring, with a monitor, a concentration of silicon monoxide contained in exhaust gas from the processing chamber; and
controlling, with a controller, an amount of the oxidant gas supplied to the processing chamber based on the concentration of silicon monoxide monitored using the monitor.

12. The method of manufacturing a semiconductor device according to claim 11, wherein the controller controls a flow rate of the oxidant gas supplied to the processing chamber so that the concentration of silicon monoxide is controlled to be within a predetermined range based on the concentration of silicon monoxide monitored by the monitor and an amount of a change thereof as time passes.

13. The method of manufacturing a semiconductor device according to claim 11, wherein an inert gas is guided to the processing chamber together with the oxidant gas, and a supply amount of the inert gas is controllable.

14. The method of manufacturing a semiconductor device according to claim 13, wherein the controller controls a flow rate of the oxidant gas supplied to the processing chamber so that the concentration of silicon monoxide is controlled to be within a predetermined range based on the concentration of silicon monoxide monitored by the monitor and an amount of a change thereof as time passes, and controls at least one of the supply amount of the inert gas, a pressure within the processing chamber, and a processing temperature within the processing chamber.

15. The method of manufacturing a semiconductor device according to claim 11, wherein O₂, H₂O or N₂O is used as the oxidant gas.

16. The method of manufacturing a semiconductor device according to claim 11, wherein N₂, Ar or He is used as the inert gas.

17. A method of manufacturing a semiconductor device comprising:
supplying an oxidant gas to a processing chamber for performing a heat treatment on a semiconductor wafer;
monitoring, with a monitor, a concentration of silicon monoxide contained in an atmosphere within the processing chamber; and
controlling, with a controller, an amount of the oxidant gas supplied to the processing chamber based on the concentration of silicon monoxide monitored using the monitor.

18. The method of manufacturing a semiconductor device according to claim 17, wherein the controller controls a flow rate of the oxidant gas supplied to the processing chamber so that the concentration of silicon monoxide is controlled to be within a predetermined range based on the concentration of silicon monoxide monitored by the monitor and an amount of a change thereof as time passes.

19. The method of manufacturing a semiconductor device according to claim 17, wherein an inert gas is guided to the processing chamber together with the oxidant gas, and a supply amount of the inert gas is controllable.

20. The method of manufacturing a semiconductor device according to claim 19, wherein the controller controls a flow rate of the oxidant gas supplied to the processing chamber so that the concentration of silicon monoxide is controlled to be within a predetermined range based on the concentration of silicon monoxide monitored by the monitor and an amount of a change thereof as time passes, and controls at least one of the supply amount of the inert gas, a pressure within the processing chamber, and a processing temperature within the processing chamber.
